(19) United States
(12) Patent Application Publication
(10) Pub. No.: US 2017/0052127 A1
(43) Pub. Date: Feb. 23, 2017

(54) PHOTODETECTOR, DETECTING APPARATUS, AND DETECTING SYSTEM

(71) Applicant: Kabushiki Kaisha Toshiba, Minato-ku (JP)

(72) Inventors: Mitsuyoshi KOBAYASHI, Ohtawara (JP); Kazuhiro ITSUMI, Koto (JP); Rei HASEGAWA, Yokohama (JP)

(73) Assignee: Kabushiki Kaisha Toshiba, Minato-ku (JP)

(21) Appl. No.: 15/234,486

(22) Filed: Aug. 11, 2016

(30) Foreign Application Priority Data
Aug. 20, 2015 (JP) 2015-163012

(51) Int. Cl. G01N 23/223; H01L 27/146

(52) U.S. Cl. CPC G01N 23/223; H01L 27/14625

(57) ABSTRACT

According to an embodiment, a photodetector includes a light converting unit, a first layer, a light detecting unit, and a second layer. The light converting unit converts radiation into light. The first layer absorbs the radiation. The light detecting unit is provided between the light converting unit and the first layer and detects light. The second layer is provided between the first layer and the light detecting unit, has a smaller average atomic weight than an average atomic weight of the first layer, and absorbs radiation scattered in the first layer and a fluorescent X-ray generated in the first layer.

### CROSS-REFERENCE TO RELATED APPLICATIONS

This application is based upon and claims the benefit of priority from Japanese Patent Application No. 2015-163012, filed on Aug. 20, 2015; the entire contents of which are incorporated herein by reference.

### FIELD

Embodiments described herein relate generally to a photodetector, a detecting apparatus, and a detecting system.

### BACKGROUND

There have been developed detecting apparatuses including a light detecting unit, such as a photodiode (PD), and a scintillator. The combination of the light detecting unit and the scintillator can provide a photon counting image having spatial resolution corresponding to the size of the scintillator. Also known are technologies for providing a computed tomography (CT) image by detecting X-rays.

The light detecting unit may possibly receive not only light resulting from conversion by the scintillator but also radiation scattered by, for example, Compton scattering in layers constituting a mounting board on which the light detecting unit is mounted. To suppress incidence of scattered radiation, there has been disclosed a configuration including radiation shielding members on the side opposite to a scintillator in a sensor section that converts radiation into charges.

### BRIEF DESCRIPTION OF THE DRAWINGS

FIG. 1 is a schematic diagram of an example of a detecting system;

FIGS. 2A and 2B are views for explaining an example of a photodetector;

FIG. 3 is a plan view of an example of the photodetector;

FIG. 4 is a sectional view of an example of the photodetector;

FIG. 5 is a view for explaining an example of scattering of radiation in a conventional photodetector;

FIG. 6 is a graph illustrating an example of an energy spectrum of light in the conventional photodetector;

FIG. 7 is a view for explaining an example of generation of light of fluorescent X-rays in the conventional photodetector;

FIG. 8 is a graph illustrating another example of the energy spectrum of light in the conventional photodetector;

FIG. 9 is a schematic diagram of an example of a section of the photodetector;

FIG. 10 is a plan view of an example of the photodetector;

FIG. 11 is a view for explaining an example of an action of the photodetector;

FIGS. 12A to 12E are views for explaining an example of a method for producing the photodetector;

FIG. 13 is a schematic diagram of an example of the photodetector;

FIG. 14 is a schematic diagram of another example of the photodetector; and

FIG. 15 is another schematic diagram of the example of the photodetector.

### DETAILED DESCRIPTION

According to an embodiment, a photodetector includes a light converting unit, a first layer, a light detecting unit, and a second layer. The light converting unit converts radiation into light. The first layer absorbs the radiation. The light detecting unit is provided between the light converting unit and the first layer and detects light. The second layer is provided between the first layer and the light detecting unit, has a smaller average atomic weight than an average atomic weight of the first laver, and absorbs radiation scattered in the first layer and a fluorescent X-ray generated in the first layer.

Embodiments are described below in detail with reference to the accompanying drawings.

### First Embodiment

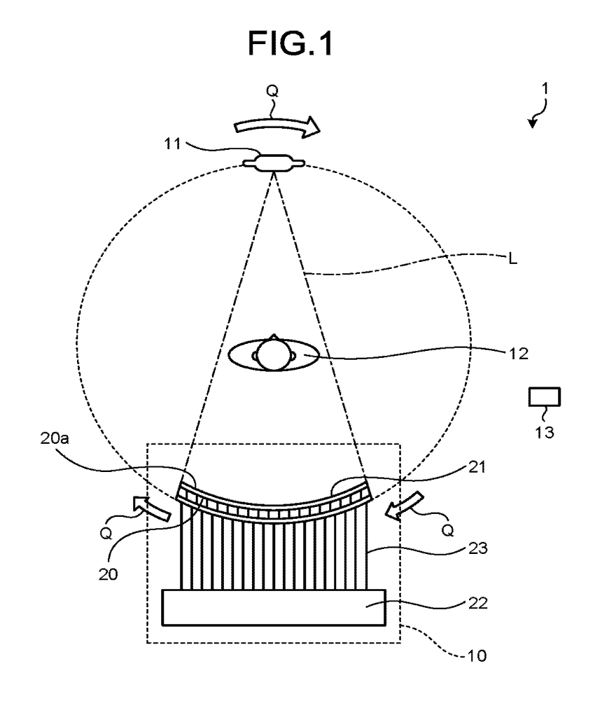

FIG. 1 is a schematic diagram of an example of a detecting system 1 according to a first embodiment. The detecting system 1 is applicable to computed tomography (CT) apparatuses, for example.

The detecting system 1 includes a light source 11, a detecting apparatus 10, and a driving unit 13. The light source 11 and the driving unit 13 are electrically connected to the detecting apparatus 10.

The light source 11 and the detecting apparatus 10 are arranged (oppositely arranged) facing each other with a space interposed therebetween. A subject 12 is positioned between the detecting apparatus 10 and the light source 11. The light source 11 and the detecting apparatus 10 are provided rotatably about the subject 12 while maintaining the oppositely arranged state.

The light source 11 emits radiation L, such as X-rays, to the detecting apparatus 10 facing the light source 11. The radiation L emitted from the light source 11 passes through the subject 12 and enters the detecting apparatus 10.

The detecting apparatus 10 detects light. The detecting apparatus 10 includes a photodetector 20 and a signal processing circuit 22. The photodetector 20 is electrically connected to the signal processing circuit 22. A plurality of photodetectors 20 in the detecting apparatus 10 according to the present embodiment are aligned in a direction of rotation of the detecting apparatus 10 (direction of the arrow Q in FIG. 1).

The photodetector 20 receives the radiation L on a first surface 20a through a collimator 21, the radiation being emitted from the light source 11 and passing through the subject 12. The first surface 20a is a two-dimersional plane on which light is incident in the photodetector 20.

The collimator 21 is arranged on th first surface 20a e of the photodetector 20 to limit the angle of the radiation L incident on the photodetector 20.

The photodetector 20 detects light. The photodetector 20 outputs a photocurrent (hereinafter referred to as a signal) corresponding to the detected light to the signal processing circuit 22 via a signal line 23. The signal processing circui 22 collectively controls the detecting system 1. The signal processing circuit 22 acquires the signal from the photodetector 20.

The signal processing circuit 22 according to the present embodiment calculates the energy and the intensity of the radiation L incident on the photodetector 20 based on the current value of the acquired signal. The signal processing circuit 22, for example, perform shaping and analog/digital (A/D) conversion on the waveform of a spectrum indicated by the signal acquired from a light detecting unit 34, thereby calculating the energy and the intensity of the radiation L incident on the photodetector 20.

The signal processing circuit 22 generates an image based on radiation information on the subject 12 from the energy and the intensity of the radiation L incident on the photodetectors 20. The signal processing circuit 22 generates a CT image of the subject 12, for example.

The detecting apparatus 10 may further include an integrated circuit (IC) and an A/D converter, for example, between the collimator 21 and the signal processing circuit 22. In this case, the collimator 21 is electrically connected to the signal processing circuit 22 via the signal line 23 and the IC or the A/D converter. With the A/D converter, the detecting apparatus 10 can digitize the signal output from the light detecting unit 34 and then transmit it to the signal processing circuit 22.

The driving unit 13 rotates the light source 11 and the detecting apparatus 10 about the subject 12 positioned therebetween while maintaining their oppositely arranged state. This configuration allows the detecting system 1 to generate a cross-sectional image of the subject 12.

While the subject 12 is a human body, for example, it is not limited thereto. The subject 12 may be an animal or a plant, or a non-living material such as an object. In other words, the detecting system 1 is applicable not only to detecting apparatuses that generate a tomographic image of human bodies, animals, and plants but also to various detecting apparatuses, such as security apparatuses, that perform fluoroscopy on objects, for example.

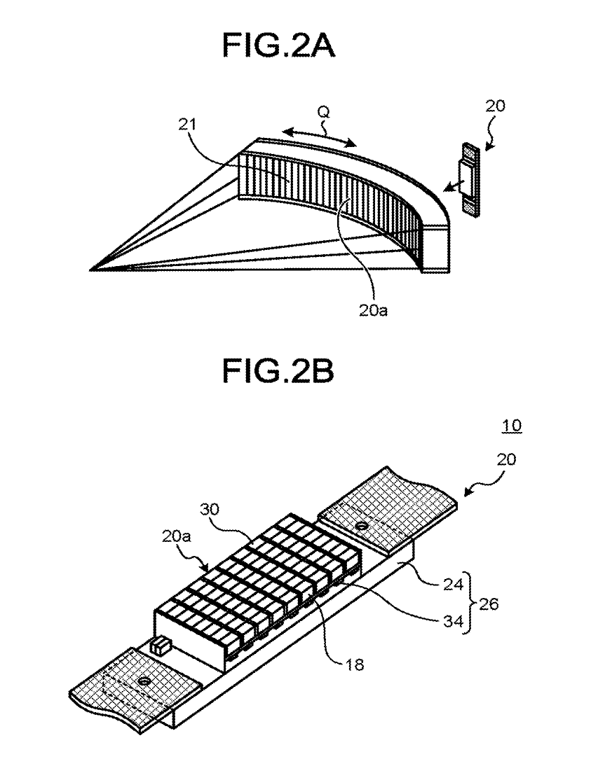

FIGS. 2A and 2B are views for explaining an example of the photodetector 20. FIG. 2A is a view of an aligned state of the photodetectors 20. The detecting apparatus 10 includes a plurality of photodetectors 20. The photodetector 20 has a rectangular shape with its long side extending in a direction that intersects with the rotation direction Q, for example. The photodetectors 20 are aligned in substantially arc shape in the direction of rotation of the photodetector 20 (refer to the arrow Q in FIG. 2A). In other words, the photodetectors 20 are filled to form a plane (tiling) along the first surface 20a serving as a light incident surface.

FIG. 2B is a schematic diagram of the photodetector 20. The photodetector 20 is detachably provided to the detecting apparatus 10. The photodetector 20 includes a mounting board 26 and scintillators 18.

The scintillator 18 is an example of a light converting unit. The scintillator 18 converts radiation, such as X-rays, into light (photons) having a longer wavelength than that of the radiation. The scintillator 18 is made of a scintillator material. The scintillator material emits fluorescence (scintillation lioht) upon incidence of radiation, such as X-rays. The scintillator material is appropriately selected depending on the application target of the detecting apparatus 10. Examples of the scintillator material include, but are not limited to, Lu₂SiO₅:(Ce), LaBr₃: (Ce), YAP (yttrium aluminum perovskite):Ce, Lu(Y)AP:Ce, etc.

The mounting board 26 includes a supporting member 24 and light detecting units 34.

The light detecting unit 34 detects light. The light detecting unit 34 is a photomultiplier tube or an avalanche photodiode (APD), for example. The APD is a known avalanche photodiode. The light detecting unit 34 according to the present embodiment is driven in a Geiger mode, for example.

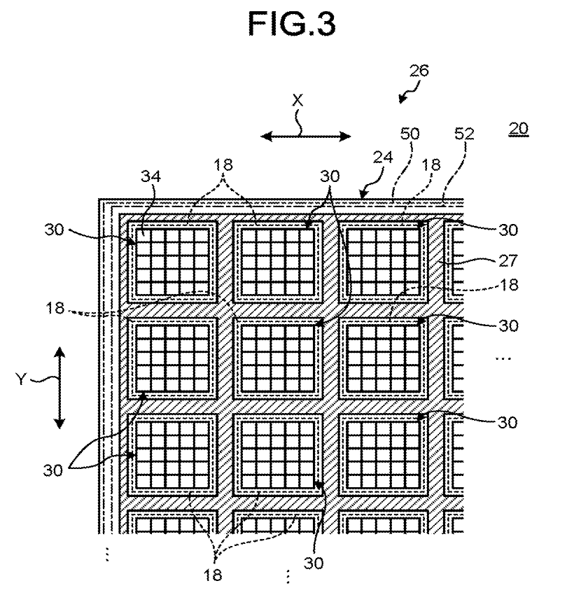

FIG. 3 is a plan view of an example of the photodetector 20. As illustrated in FIG. 3, a plurality of light detecting units 34 are arranged in a matrix (refer to a direction of the arrow X and a direction of the arrow Y in FIG. 3). In the photodetector 20, the light detecting units 34 correspond to one pixel (refer to a pixel area 30), and a plurality of pixel areas 30 are arranged in a matrix. Arrangement in a matrix means arrangement in a row direction (direction of the arrow X) and in a column direction (direction of the arrow Y). The row direction (direction of the arrow X) and the column direction (direction of the arrow Y) are directions orthogonal to each other on the first surface 20a of the light detecting units 34. The structure having the light detecting units 34 in each pixel area 30 can facilitate replacement of the photodetector 20 in repairing, for example.

In FIG. 3, the pixel areas 30 each include 25 (5×5) light detecting units 34. The number of light detecting units 34 constituting the pixel area 30, however, is given by way of example only and is not limited to 25. A reflective member 27 that reflects light may be provided between the pixel areas 30.

The scintillators 18 are arranged on the first surface 20a side of the light detecting unit 34. The scintillators 18 are arranged at positions corresponding to the respective pixel areas 30. Specifically, the scintillators 18 are arranged such that areas obtained by projecting the scintillators 18 onto the light detecting units 34 in the thickness direction of the scintillators 18 (corresponding to the thickness direction of the light detecting units 34) cover the respective pixel areas 30 each composed of the light detecting units 34.

The scintillators 18 may be arranged in a manner corresponding to the respective light detecting units 34. Alternatively, the scintillators 18 may be arranged in a manner continuously covering a plurality of pixel areas 30. In other words, the scintillators 18 may be arranged in a manner continuously covering a plurality of light detecting units 34 in a plane direction of the first surface 20a.

The photodetector 20 according to the present embodiment further includes a first layer 50 and a second layer 52. In this example, the photodetector 20 also includes the supporting member 24. The first layer 50, the second layer 52, and the supporting member 24 will be described later in detail.

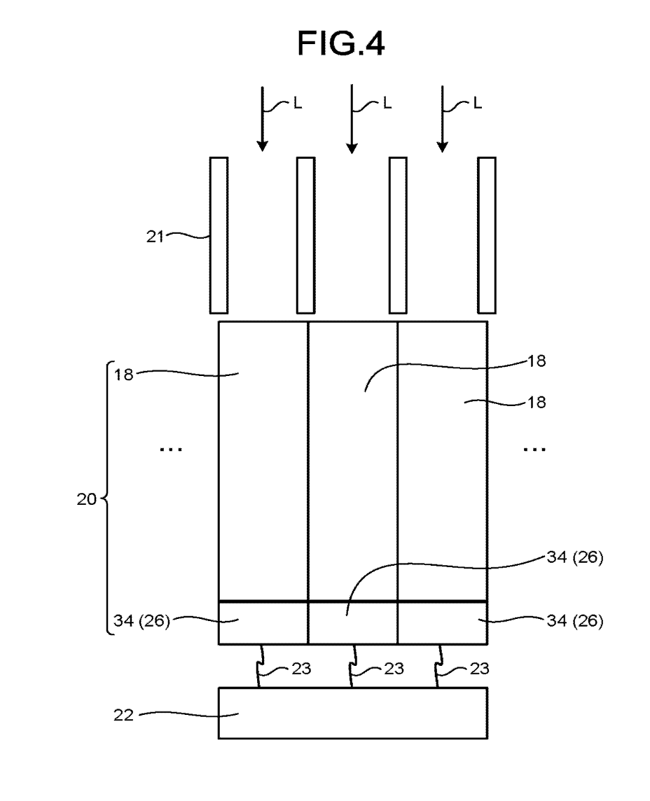

FIG. 4 is a schematic illustrating an example of a sectional view of the photodetector 20. In FIG. 4, the scintillators 18 are arranged at positions corresponding to the respective light detecting units 34, for example.

In the photodetector 20, the scintillators 18 are stacked on the mounting board 26 that is provided with the light detecting units 34. The collimators 21 are arranged above the scintillators 18.

In the example illustrated in FIG. 4, the collimators 21 are arranged at positions corresponding to respective boundaries between adjacent scintillators 18 in a direction orthogonal to the thickness direction of the mounting board 26. In this case, the collimators 21 have a function to limit the incident angle to the scintillators 18 of the radiation L incident on the scintillators 18. In other words, the collimators 21 have a function to suppress incidence, on the scintillators 18, of radiation L having a large incident angle to the scintillators 18.

The radiation L having a large incident angle to the scintillators 18 is more likely to generate photons in adjacent scintillators 18 simultaneously. To address this, the collimators 21 are arranged at positions corresponding to respective boundaries between adjacent scintillators 18 on the side of the scintillators 18 opposite to the light detecting unit 34. This structure can suppress deterioration of the detection accuracy.

The incident angle to the scintillators 18 according to the present embodiment means an angle from an axial direction corresponding to the thickness direction of the scintillators 18. The thickness direction of the scintillators 18 corresponds to a direction orthogonal to the array direction of the scintillators 18 and the light detecting units 34 and the thickness direction of the mounting board 26.

The radiation L incident on the scintillators 18 through the collimators 21 is converted into light (photons) having a longer wavelength than that of the radiation L by the scintillators 18. The light then reaches the mounting board 26 including the light detecting units 34. The light (photons) having a longer wavelength than that of the radiation L resulting from conversion by the scintillators 18 may be hereinafter simply referred to as light.

The light detecting units 34 provided on the mounting board 26 detect the incident light. The photodetectors 20 output signals based on the detected light to the signal processing circuit 22 via the signal lines 23.

The surface of the scintillators 18 and the areas between adjacent scintillators 18 may be provided with a reflective member or a reflective layer that reflects photons. Furthermore, a portion between the scintillators 18 and the light detecting units 34 may be provided with a resin layer having a light-guide function to guide the light resulting from conversion by the scintillators 18 to the light detecting units 34. The scintillators 18 and the collimators 21 may be arranged in contact with each other or with a predetermined gap interposed therebetween.

In the conventional technologies, the light detecting units 34 may possibly receive not only the light resulting from conversion by the scintillators 18 but also radiation scattered in the layers constituting the mounting board 26 and fluorescent X-rays generated by incidence of the radiation L on the layers constituting the mounting board 26.

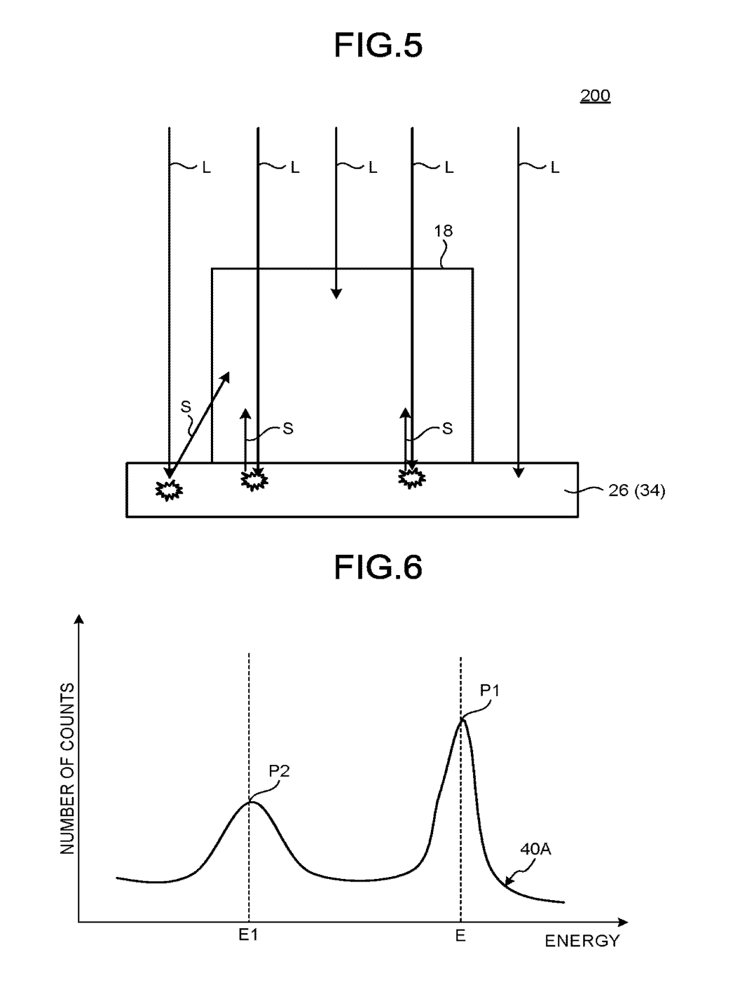

FIG. 5 is a view for explaining an example of scattering of radiation in a conventional photodetector 200. Part of the radiation L incident on the photodetector 202 may possibly reach the mounting board 26 without passing through the scintillator 18. Furthermore, part of the radiation L incident on the photodetector 200 may possibly reach the mounting board 26 without being absorbed by the scintillator 18. When scintillator 18 is made of a scintillator material of a lower density, the radiation L is more likely to pass through the scintillator 18 and reach the mounting board 26, for example.

If photons of the radiation L that reach the mounting board 26 are scattered in any of the layers constituting the mounting board 26, the photons of scattered radiation S may possibly reach the scintillator 18. The photons that reach the scintillator 18 are converted by the scintillator 18 and then reach the light detecting unit 34.

In this case, the light detecting unit 34 detects light obtained by converting, by the scintillator 18, the radiation L incident on the scintillator 18 from the outside and also detects light obtained by converting, by the scintillator 18, the photons of the radiation S from the mounting board 26.

Specifically, energy E1 of photons of the radiation S generated in a direction different by 180 degrees from the direction of incidence on the mounting board 26 is represented by Expression (1) in megaelectron volts (MeV).

E1=E/(1×E×3.91) (1)

In Expression (1), E1 denotes energy of photons of the radiation S scattered in a direction opposite to the incident direction, that is, energy of back-scattered photons, and E denotes energy of the radiation L incident on the photodetector 200 from the outside.

FIG. 6 is a graph 40A illustrating an example of an energy spectrum calculated from the number of photons detected by the light detecting unit 34 in the conventional photodetector 200.

In a case where radiation having single energy E is incident on the photodetector 200, for example, the light detecting unit 34 detects light represented by an energy spectrum having a peak P1 and a peak P2. The peak P1 is a peak of energy of light obtained by converting, by the scintillator 18, the radiation L incident on the photodetector 200 from the outside. The peak P2 is energy of the radiation S.

The light detecting unit 34 of the conventional photodetector 200 thus detects not only the energy at the peak P1 to be originally detected but also the energy at the peak P2 caused by the radiation S. As a result, the detection accuracy deteriorates.

As the ratio of generation of the radiation S to the light obtained by converting the radiation L by the scintillator 18 increases, the ratio of the number of photons that form the peak P2 to that of the peak P1 increases. As a result, the detection accuracy further deteriorates.

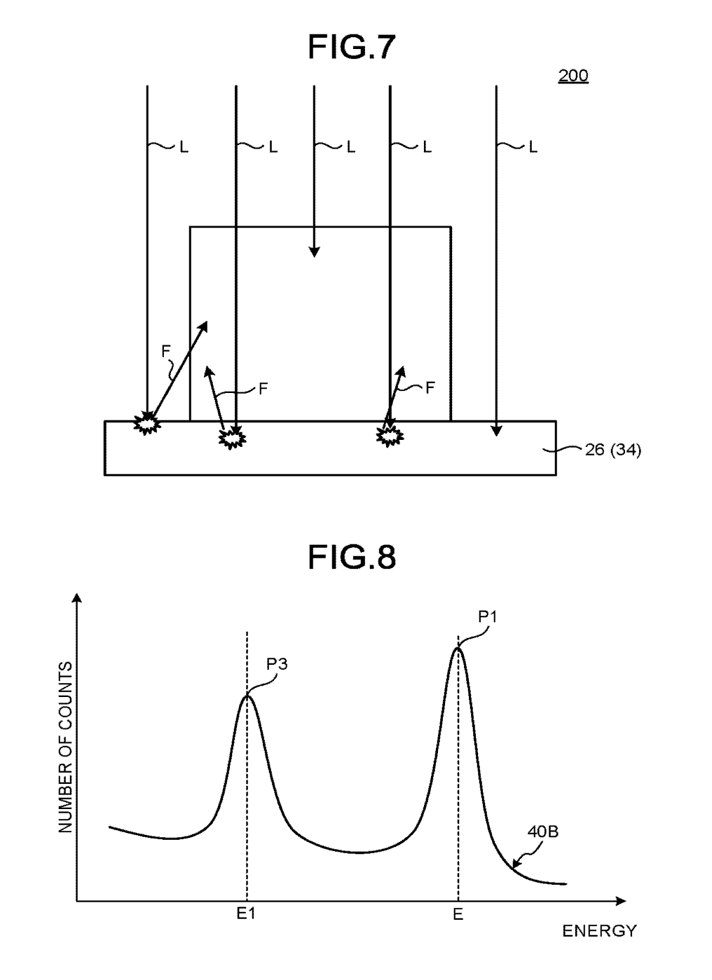

FIG. 7 is a view for explaining generation of fluorescent X-rays in the conventional photodetector 200.

Part of the radiation L incident on the photodetector 200 may possibly reach the mounting board 26 without passing through the scintillator 18. Furthermore, part of the radiation L incident on the photodetector 200 may possibly reach the mounting board 26 without being absorbed by the scintillator 18.

If part of photons of the radiation L that reach the mounting board 26 reach the layers constituting the mounting board 26, fluorescent X-rays specific to the layers may possibly be generated.

Generated fluorescent X-rays F may possibly reach the scintillator 18. The fluorescent X-ray F that reach the scintillator 18 are converted by the scintillator 18 and reach the light detecting unit 34.

In this case, the light detecting unit 34 detects light obtained by converting the radiation L by the scintillator 18 and light obtained by converting the fluorescent X-rays F by the scintillator 18.

FIG. 8 is a graph 40B illustrating an example of an energy spectrum of light detected by the light detecting unit 34 in the conventional photodetector 200.

As illustrated in FIG. 8, the conventional light detecting unit 34 detects light represented by an energy spectrum having the peak P1 and a peak P3. The peak P1 is the same as the peak P1 described above. The peak P3 is a peak of energy of the fluorescent X-rays F.

The conventional light detecting unit 34 detects not only the energy at the peak P1 to be originally detected but also the energy the peak P3 caused by the fluorescent X-rays F. As a result, the detection accuracy deteriorates.

As described with reference to FIGS. 5 to 8, the conventional light detecting unit 34 may possibly detect not only the energy at the peak P1 to be originally detected but also the energy at the peak P2 caused by the scattered radiation S and the energy at the peak P3 caused by the fluorescent X-rays F. As a result, the detection accuracy of the conventional photodetector 200 deteriorates.

To address this, the photodetector 20 according to the present embodiment includes the first layer 50 and the second layer 52.

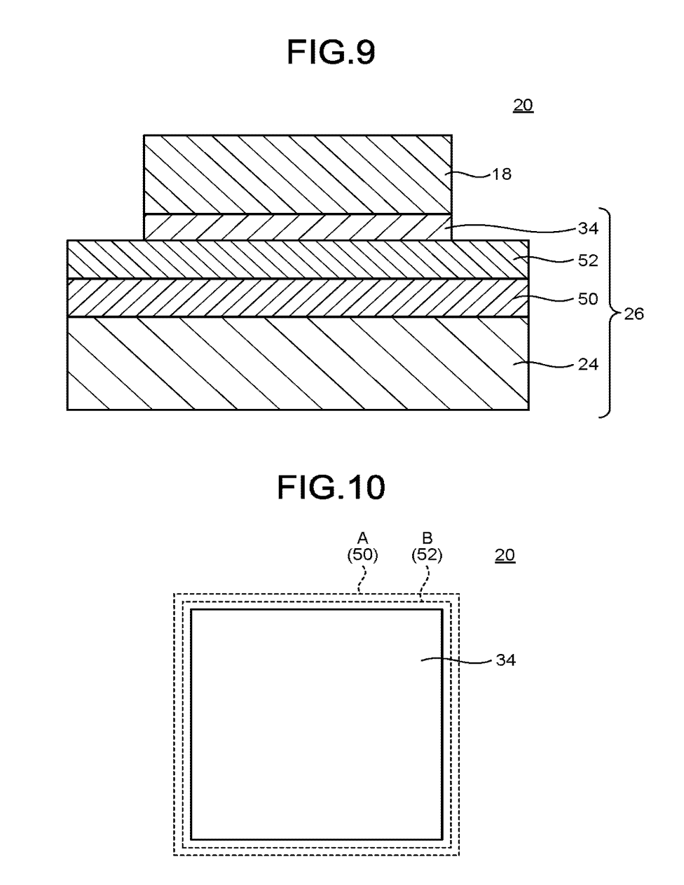

FIG. 9 is a schematic diagram of an example of a section of the photodetector 20 according to the present embodiment. The first layer 50 is provided on the side of the light detecting unit 34 opposite to the scintillator 18 in the thickness direction with the second layer 52 interposed between the first layer 50 and the light detecting unit 34. In other words, the light detecting unit 34 is provided between the scintillator 18 and the first layer 50. The second layer 52 is provided between the light detecting unit 34 and the first layer 50.

In other words, the photodetector 20 according to the present embodiment has a structure obtained by stacking the first layer 50, the second layer 52, the light detecting unit 34, and the scintillator 18 on the supporting member 24 in this order.

A multilayer stack obtained by stacking the supporting member 24, the first layer 50, the second layer 52, and the light detecting unit 34 in this order may be referred to as the mounting board 26. The mounting board 26 does not necessarily include the supporting member 24.

The first layer 50 absorbs the radiation L. The first layer 50 has a larger average atomic weight than that of the second layer 52.

The first layer 50 may absorb at least part of the radiation L. The first layer 50 may preferably absorb or transmit 50% or more of the incident radiation L and more preferably absorb 90% or more of the incident radiation L.

At least part of the radiation L incident on the first layer 50 is absorbed by the first layer 50. As a result, the first layer 50 suppresses generation of the radiation S scattered in the first layer 50 and generation of fluorescent X-rays specific to the first layer 50.

The average atomic weight of the first layer 50 and the second layer 52 according to the present embodiment means an average atomic weight of elements other than impurities included in the first layer 50 and the second layer 52. The impurities mean elements of equal to or less than 5% by weight to a total quantity of materials constituting the first layer 50 and the second layer 52 of 100% by weight.

The first layer 50 preferably includes elements having a larger atomic number. Elements having a larger atomic number mean elements the atomic number of which is larger than the largest atomic number of elements included in the second layer 52.

The first layer 50 may include the same element as the element having the largest atomic number out of the elements included in the second layer 52. In this case, the content rate of the element having the largest atomic number included in the first layer 50 is higher than that of the second layer 52.

The first layer 50 preferably includes at least one kind of element selected from Ag, Cu, Fe, and Mo, for example. To suppress the radiation S, the first layer 50 especially preferably includes at least Ag out of these elements.

The first layer 50 may be made of one kind of element or a compound or a mixture of a plurality of kinds of elements.

The thickness of the first layer 50 simply needs to satisfy the functions and the requirements described above and is not limited. In other words, the first layer 50 simply needs to have a thickness with which the first layer 50 can maintain the function to absorb at least part of the radiation L. The first layer 50 has a larger weight than that of the second layer 52 because it has a larger average atomic weight than that of the second layer 52. The thickness of the first layer 50 is appropriately adjusted depending on the weight and the size of the photodetector 20 required in mounting the photodetector 20 on various apparatuses or devices.

The thickness direction according to the present embodiment corresponds to a stacking direction of the first layer 50, the second layer 52, the light detecting unit 34, and the scintillator 18.

As described above, the first layer 50 is positioned on the side of the second layer 52 opposite to the light detecting unit 34 in the thickness direction of the photodetector 20. The position of the first layer 50 in the plane direction orthogonal to the thickness direction preferably corresponds to the position of the light detecting unit 34.

FIG. 10 is a plan view schematically illustrating an example of the photodetector 20 viewed from the light detecting unit 34. As illustrated in FIG. 10, the first layer 50 is preferably arranged such that a first projection area A obtained by projecting the first layer 50 onto the light detecting unit 34 covers at least the light detecting unit 34. The first layer 50 preferably has such a size in the plane direction and is arranged at such a position in the photodetector 20 that the first projection area A covers the light detecting unit 34.

Referring back to FIG. 9, the second layer 52 is provided between the first layer 50 and the light detecting unit 34 as described above.

The second layer 32 has a smaller average atomic weight than that of the first layer 50. The second layer 52 transmits at least part of the incident radiation L. Specifically, the second layer 52 transmits at least part of photons of the radiation L. The second layer 52 preferably transmits all the incident radiation L. In other words, the second layer 52 preferably transmits all the photons of the radiation L in the thickness direction.

The second layer 52 absorbs the radiation S scattered in the first layer 50 and the fluorescent X-rays F generated in the first layer 50 by the radiation L incident or the first layer 50.

In other words, the second layer 52 absorbs the radiation S and the fluorescent X-rays F output from the first layer 50 and incident on the second layer 52. As a result, the second layer 52 can prevent the radiation S and the fluorescent X-rays F from reaching the light detecting unit 34.

The second layer 52 may absorb at least part of the radiation S and the fluorescent X-rays F. The second layer 52 may preferably absorb 50% or more of the radiation S and the fluorescent X-rays F output from the first layer 50 and incident on the second layer 52 and more preferably absorb 90% or more of the radiation S and the fluorescent X-rays F.

The second layer 52 simply needs to be made of a material that satisfies the functions and the requirements described above. The second layer 52, for example, preferably includes elements having a smaller atomic number than that of the first layer 50. Elements having a smaller atomic number mean elements the atomic number of which is smaller than the largest atomic number of elements included in the first layer 50.

The second layer 52 preferably includes at least one kind of element selected from Si, Al, and Mg, for example. To reduce the energy of the fluorescent X-rays F and facilitate the production, the second layer 52 especially preferably includes at least Si out of these elements.

The second layer 52 may be made of one kind of element or a compound or a mixture of a plurality of kinds of elements.

The second layer 52 needs to have a smaller average atomic weight than that of the first layer 50. The second layer 52 is especially preferably made of an element the atomic number of which is smaller than the smallest atomic number of an element in materials constituting the first layer 50.

The thickness of the second layer 52 simply needs to satisfy the functions and the requ plan view irements described above is not limited. Specifically, the second layer 52 needs to have a thickness of equal to or larger than a thickness with which the second layer 52 can absorb the fluorescent X-rays F generated in the first layer 50. The second layer 52 also needs to have a thickness with which the second layer 52 transmits the radiation L incident on the surface thereof on the light dtecting unit 34 side to the first layer 50.

In other words, the second layer 52 needs to have a thickness with which the second layer 52 can transmit the radiation L incident thereon without scattering it in the second layer 52.

The thickness of the second layer 52 is adjusted to a thickness that satisfies the conditions described above depending on the materials of the second layer 52 and the materials of the first layer 50.

In a case where the second layer 52 is made of Si, and the first later 50 is made of Ag, for example, the second layer 52 preferably has a thickness of equal to or larger than 0.5 mm and equal to or smaller than 2 mm. The second layer 52 having the thickness described above can effectively suppress generation of the scattered radiation S in the second layer 52. Specifically, the second layer 52 made of Si and having a thickness falling within the range can provide an advantageous effect of suppressing generation of the radiation S substantially equivalent to that provided when the second layer 52 is made of Mo.

As described above, the second layer 52 is positioned between the light detecting unit 34 and the first layer 50 in the thickness direction of the photodetector 20. The position of the second layer 52 in the plane direction orthogonal to the thickness direction preferably corresponds to the position of the light detecting unit 34.

Specifically, as illustrated in FIG. 10, the second layer 52 is preferably arranged such that a second projection area B obtained by projecting the second layer 52 onto the light detecting unit 34 covers at least the light detecting unit 34. The second layer 52 preferably has such a size in the plane direction and is arranged at such a position in the photodetector 20 that the second projection area B covers the light detecting unit 34.

Referring back to FIG. 9, one of the first layer 50 and the second layer 52 may be electrically conductive. In this case, one of the first layer 50 and the second layer 52 is made of an electrically conductive material that can provide the functions and the requirements described above.

In a case where one of the first layer 50 and the second layer 52 is electrically conductive, the electrically conductive layer out of the first layer 50 and the second layer 52 may function as a wiring layer or a ground layer. The ground layer has a reference potential. The reference potential may be referred to as a ground potential.

The supporting member 24 is provided on the side of the first layer 50 opposite to the second layer 52 in the thickness direction.

The supporting member 24 supports the first layer 50, the second layer 52, and the light detecting unit 34 in the mounting board 26. The photodetector 20 (mounting board 6) does not necessarily include the supporting member 24.

With the supporting member 24, the photodetector 20 can secure the strength of the entire mounting board 26.

A material of the supporting member 24 is not limited. The supporting member 24, for example, may have an average atomic weight of any one of equal to or smaller than that of the second layer 52, larger than that of the second layer 52 and smaller than that of the first layer 50, and equal to or larger than that of the first layer 50.

In a case where the supporting member 24 has an average atomic weight of equal to or smaller than that of the second layer 52, the weight of the mounting board 26 (and the photodetector 20) can be reduced.

In a case where the supporting member 24 has an average atomic weight of larger than that of the first layer 50, the average atomic weight increases in order of the second layer 52, the first layer 50, and the supporting member 24. In this case, the photodetector 20 can suppress generation of fluorescent X-rays F having higher light energy.

The thickness of the supporting member 24 is not limited. The thickness of the supporting member 24 is appropriately adjusted depending on the material of the supporting member 24 and on the weight and the size of the photodetector 20 required in mounting the photodetector 20 on various apparatuses or devices.

At least one of the thicknesses of the first layer 50 and the supporting member 24 may be adjusted so as to function as a shielding layer that shields, from the radiation L, the signal processing circuit 22 (refer to FIGS. 1 and 4) arranged on the side of the mounting board 26 opposite to the scintillator 18.

The supporting member 24, the first layer 50, and the second layer 52 preferably have a uniform thickness in the plane direction (direction orthogonal to the thickness direction) in an area other than portions like via holes formed in production of the photodetector 20. The uniformity in the thickness makes the generation rate of the radiation S and the fluorescent X-rays F and the transmittance and the absorbance of the radiation L uniform in the plane direction in the supporting member 24, the first layer 50, and the second layer 52. As a result, the signal processing circuit 22 can reduce the load in correcting the waveform of the spectrum indicated by the signals acquired from the light detecting units 34. in view of the uniformity, the sectional area of the via holes formed in the layers constituting the mounting board 26 (the supporting member 24, the first layer 50, and the second layer 52) in the plane direction is preferably made as small as possible.

The following describes an action when the radiation L is incident on the photodetector 20.

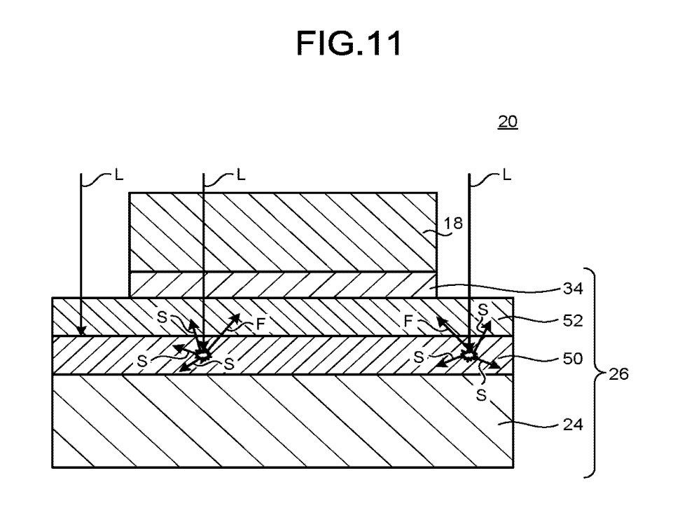

FIG. 11 is a view for explaining an example of an action when the radiation L is incident on the photodetector 20. The radiation L is incident on the photodetector 20 from the scintillator 18 side.

The radiation L incident on the scintillator 18 is converted into light and reaches the light detecting unit 34. The radiation L not converted into light by the scintillator 18 passes through the light detecting unit 34 and the second layer 52 and then reaches the first layer 50. Part of the radiation L incident on the photodetector 20 may possibly reach the first layer 50 without passing through the scintillator 18.

The first layer 50 absorbs at least part of the radiation L incident thereon. This mechanism suppresses scattering, in the first layer 50, of photons of the radiation L that have reached the first layer 50. As a result, the first layer 50 can suppress generation of the scattered radiation S.

As described above, the first layer 50 has a larger average atomic weight than that of the second layer 52. As the atomic number of elements constituting the first layer 50 is larger, the absorbance of the incident radiation L is higher. By contrast, as the atomic number of elements constituting the first layer 50 is larger, the energy of the fluorescent X-rays F is larger.

Therefore, when the radiation L is incident on the first layer 50, fluorescent X-rays specific to the first layer 50 are generated in the first layer 50. The fluorescent X-rays F generated in the first layer 50 reach the second layer 52.

As a result, the second layer 52 receives the radiation S scattered in the first layer 50 and the fluorescent X-rays F generated in the first layer 50 by the radiation L not absorbed by the first layer 50.

The second layer 52 absorbs the radiation S and the fluorescent X-rays F. In other words, the radiation S and the fluorescent X-rays F traveling from the first layer 50 to the second layer 52 are absorbed by the second layer 52. This mechanism can suppress incidence of the radiation S scattered in the first layer 50 and the fluorescent X-rays F generated in the first layer 50 on the light detecting unit 34 besides the light resulting from conversion by the scintillator 18.

As a result, the signal processing circuit 22 receives signals output based on light accurately detected by the light detecting units 34. The energy of the radiation L lost by the scintillator 18 is proportional to the number of photons of the light resulting from conversion by the scintillator 18. The signal processing circuit 22 calculates the number of photons of the light resulting from conversion by the scintillator 18 using the signals received from the light detecting unit 34. The signal processing circuit 22 thus can calculate backward the energy of the radiation L incident on the scintillator 18.

Signals obtained by amplifying signal electrons in an avalanche manner by, for example, an APD are known to have statistical fluctuation. Furthermore, a peak of an energy spectrum detected by an APD is known to have a width even in a case where X-rays having single energy are output to the light detecting unit 34 (APD). To address this, the signal processing circuit 22 preferably calculates the energy of the radiation L incident on the photodetector 20 by performing a known analysis method, such as fitting, on the energy spectrum obtained from the signals received from the light detecting unit 34.

As described above, the photodetector 20 according to the present embodiment includes the scintillator 18, the second layer 52, the light detecting unit 34, and the first layer 50. The scintillator 18 converts the radiation L into light having a longer wavelength than that of the radiation L. The first layer 50 absorbs the radiation L. The light detecting unit 34 is provided between the scintillator 18 and the first layer 50 and detects light. The second layer 52 is provided between the first layer 50 and the light detecting unit 34. The second layer 52 has a smaller average atomic weight than that of the first layer 50 and transmits the radiation L. The second layer 52 absorbs the radiation S scattered in the first layer 50 and the fluorescent X-rays F generated in the first layer 50 by the radiation L incident on the first layer 50.

As such, the photodetector 20 according to the present embodiment includes the first layer 50 and the second layer 52. The first layer 50 absorbs at least part of the radiation L. The second layer 52 absorbs the radiation S scattered in the first layer 50 and the fluorescent X-rays F. The second layer 52 is provided between the light detecting unit 34 and the first layer 50. This configuration allows the photodetector 20 to absorb at least part of the radiation L with the first layer 50 and absorb the radiation S and the fluorescent X-rays F with the second layer 52. As a result, the photodetector 20 according to the present embodiment can suppress incidence of the radiation S scattered in the first layer 50 and the fluorescent X-rays F on the light detecting unit 34.

Consequently, the photodetector 20 according to the present embodiment can improve the accuracy in detecting the radiation L.

Production Method

The following describes an example of a method for producing the photodetector 20 according to the present embodiment.

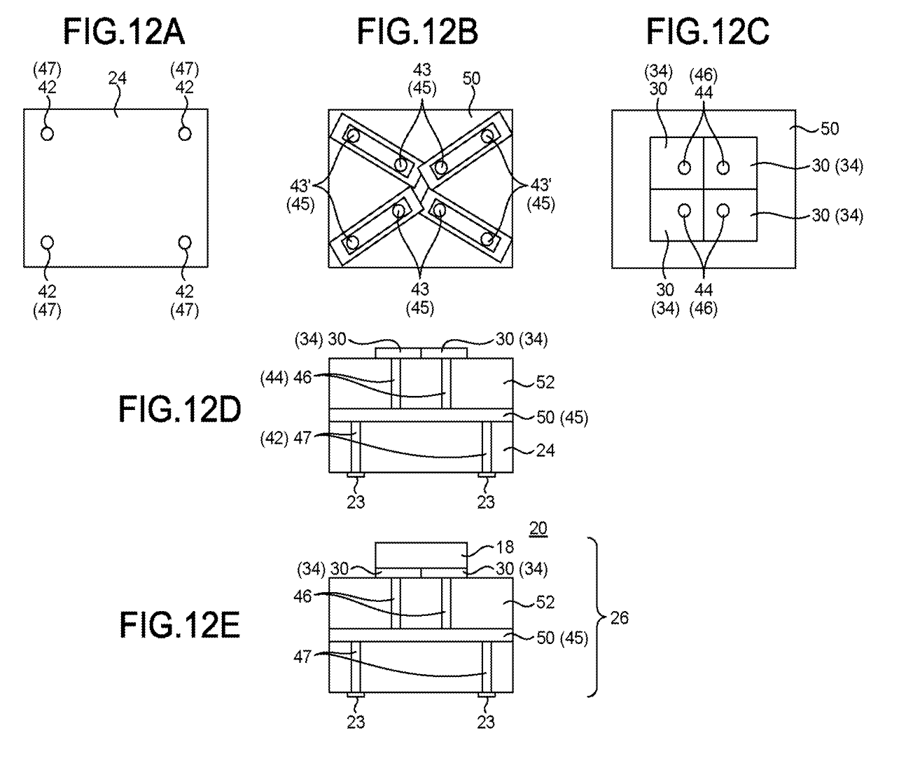

FIGS. 12A to 12E are views for explaining an example of the method for producing the photodetector 20. The production method illustrated in FIGS. 12A to 12E is given by way of example only, and the method for producing the photodetector 20 is not limited thereto.

The supporting member 24, the first layer 50, and the second layer 52 are prepared first (refer to FIGS. 12A to 12C).

For example, a plate-like supporting member 24 is prepared and via holes 42 are formed on the supporting member 24 (refer to FIG. 12A). The via holes 42 are filled with an electrically conductive material to serve as through electrodes 47. The formation of the via holes 42 and the filling thereof with the electrically conductive material are performed by a known method. Signal lines 23 are printed on the supporting member 24 (refer to FIG. 12D). The signal lines 23 transmit signals from the light detecting units 34 to the signal processing circuit 22. The signal lines 23 are printed by a known method.

A plate-like second layer 52 is prepared, and via holes 44 are formed at positions corresponding to the respective pixel areas 30 on the second layer 52 (refer to FIG. 12C). The via holes 44 are filled with an electrically conductive material to serve as through electrodes 46. The formation of the via holes 44 and the filling thereof with the electrically conductive material are performed by a known method.

A plate-like first layer 50 is prepared, and at least one of via holes 43 and via holes 43′ are formed on the first layer 50 to electrically connect the electrically conductive material in the via holes 42 of the supporting member 24 to the electrically conductive material in the via holes 44 of the second layer 52 (refer to FIG. 12B). Specifically, to form wirings on the surface of the first layer 50, via holes, out of the via holes 43 and the via holes 43′, that need to be formed through the first layer 50 are formed for the electrical connection. The via holes 43 are filled with an electrically conductive material to serve as through electrodes 45. The formation of the via holes 43 and the filling thereof with the electrically conductive material are performed by a known method.

The supporting member 24, the first layer 50, and the second layer 52 are stacked in this order. The positions of the supporting member 24, the first layer 50, and the second layer 52 are adjusted such that the through electrodes 47, 45, and 46 are electrically connected in this order between layers that are adjacent in the thickness direction (refer to FIG. 12D). The supporting member 24 is arranged with its surface provided with the signal lines 23 facing the side opposite to the first layer 50.

The multilayer stack obtained by stacking the supporting member 24, the first layer 50, and the second layer 52 in this order is pressurized and burnt. Subsequently, the light detecting units 34 are formed on the respective pixel areas 30 on the second layer 52. The light detecting units 34 are formed by a known method.

Subsequently, the scintillator 18 is arranged on the light detecting units 34, thereby producing the photodetector 20 (refer to FIG. 12E).

While the layers constituting the photodetector 20 (the supporting member 24, the first layer 50, and the second layer 52) are pressurized and burnt in the example illustrated in FIGS. 12A to 12E, the method for producing the photodetector 20 is not limited thereto. The photodetector 20 may be produced by bonding the layers with adhesive layers interposed therebetween or applying or vapor-depositing the materials of the layers, for example. Th photodetector 20 may be produced by a combination of at least two of pressure-burning, vapor deposition, and application. The photodetector 20 may be produced by performing resistant burning or plating after pressure-burning.

The photodetector 20 produced by the production method illustrated in FIGS. 12A to 12E has the through electrodes 46, 45, and 47 as illustrated in FIG. 12E. The through electrodes 46, the through electrodes 45, and the through electrodes 47 are used to electrically connect the light detecting units 34 of the photodetecton 20 to the signal processing circuit 22 (not illustrated in FIGS. 12A to 12E). The light detecting units 34 are electrically connected to the signal processing circuit 22 via the through electrodes 46, 45, and 47 and the signal lines 23 formed on the surface of the supporting member 24 on the side opposite to the first layer 50.

The signals output from the light detecting units 34 can be retrieved from the back surface of the photodetector 20 (surface on the side opposite to the scintillator 18) via the through electrodes 46, 45, and 47. This configuration enables the light detecting units 34 to be densely mounted on the second layer 52.

In a case where the first layer 50 is electrically conductive, setting the electric potential of the first layer 50 to the reference potential (ground potential) can electrically separate the signal lines 23 and the through electrodes 46, 45, and 47 from the other portions on the mounting board 26. Furthermore, setting the electric potential of the first layer 50 to the reference potential can increase the strength of the photodetector 20 against noise.

### Second Embodiment

A second embodiment describes the photodetector 20 further including a ground (GND) layer and a wiring layer.

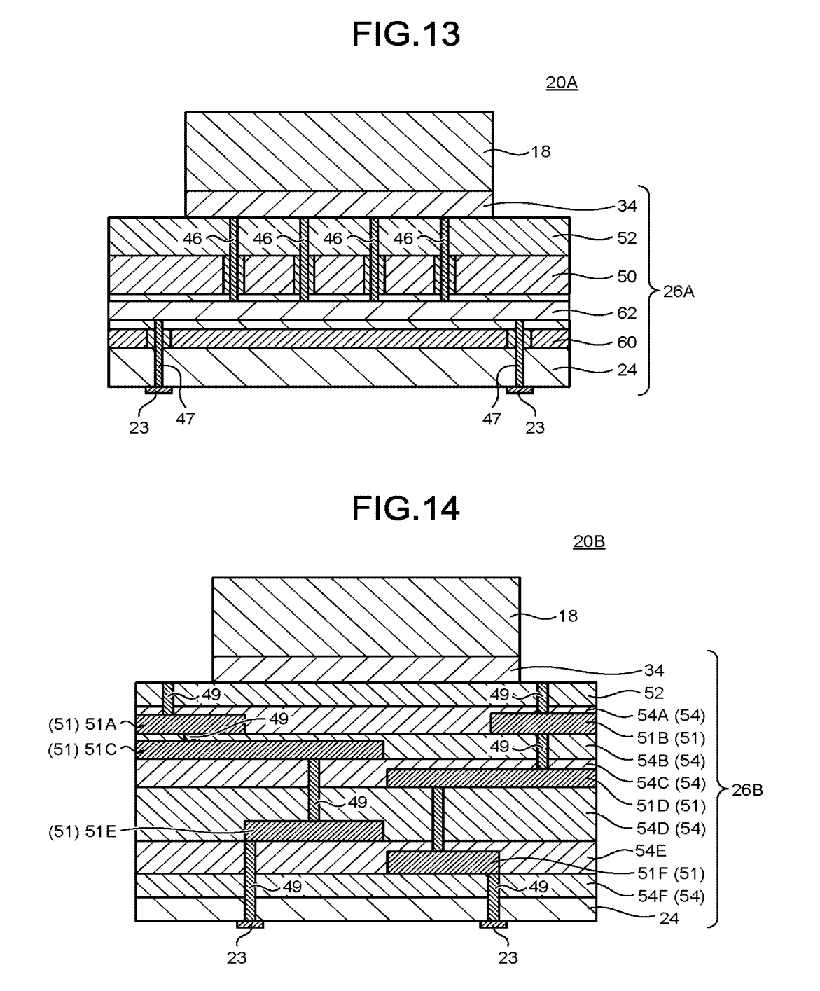

FIG. 13 is a schematic diagram of an example of a photodetector 20A according to the present embodiment.

The photodetector 20A includes the scintillator 18 on a mounting board 26A. The mounting board 26A has a structure obtained by stacking the supporting member 24, a ground layer 60, a wiring layer 62, the first layer 50, the second layer 52, and the light detecting unit 34 in this order.

The supporting member 24, the first layer 50, the second layer 52, the light detecting unit 34, and the scintillator 16 are identical with those according to the first embodiment.

The first layer 50 according to the present embodiment is electrically conductive.

The wiring layer 62 is provided between the first layer 50 and the supporting member 24. In other words, the first layer 50 and the wiring layer 62 are separated to serve as different layers in the photodetector 20A.

The wiring layer 62 is electrically connected to the light detecting unit 34 via the through electrodes 46. The wiring layer 62 is also electrically connected to the signal lines 23 via the through electrodes 47. The through electrodes 46 are provided through the first layer 50 and the second layer 52 to electrically connect the light detecting unit 34 to the wiring layer 62. The through electrodes 47 are provided through the ground layer 60 and the supporting member 24 to electrically connect the wiring layer 62 to the signal lines 23.

At least part of the wiring layer 62 is electrically conductive, and the material thereof is not limited. Signals output from the light detecting unit 34 are transmitted to the signal processing circuit 22 (refer to FIG. 1) via the through electrodes 46, the wiring layer 62, the through electrodes 47, and the signal lines 23.

The ground layer 60 has the reference potential and is provided between the wiring layer 62 and the supporting member 24. The ground layer 60 is arranged so as not to be in electrically contact with (electrically connected to) the through electrodes 46, the wiring layer 62, the through electrodes 47, and the signal lines 23.

The ground layer 60 is electrically connected to the electrically conductive first layer 50. The ground layer 60 and the first layer 50 have the same potential (that is, the reference potential). The wiring layer 62 is sandwiched in the thickness direction between the first layer 50 and the ground layer 60 having the reference potential.

Therefore, the first layer 50 of the photodetector 20A has a function of a noise guard for the wiring layer 62 besides the functions described in the first embodiment. As described above, the wiring layer 62 is sandwiched between the first layer 50 and the ground layer 60, and the first layer 50 and the ground layer 60 have the reference potential. This configuration can increase the strength of the photodetector 20A against noise.

As described above, the photodetector 20A according to the present embodiment includes the scintillator 18, the light detecting unit 34, the second layer 52, the electrically conductive first layer 50, the wiring layer 62, and the ground layer 60. The ground layer 60 is not electrically connected to the light detecting unit 34 and is electrically connected to the electrically conductive first layer 50. The ground layer 60 and the first layer 50 have the same potential. The wiring layer 62 is provided between the ground layer 60 and the first layer 50 and is electrically connected to the light detecting unit 34.

Consequently, the photodetector 20A according to the present embodiment can not only provide the advantageous effects of the photodetector 20 according to the first embodiment but also further improve the detection accuracy.

### Third Embodiment

While the first layer 50 according to the embodiments described above is a single layer, it may be a multilayer stack made of a plurality of layers.

FIG. 14 is a schematic diagram of an example of a photodetector 20B according to a third embodiment.

The photodetector 20B includes the scintillator 18 on a mounting board 26B. The mounting board 26B has a structure obtained by stacking the supporting member 24, a first layer 51, the second layer 52, and the light detecting unit 34 in this order.

The supporting member 24, the second layer 52, the light detecting unit 34, and the scintillator 18 are identical with those according to the first embodiment.

The first layer 51 according to the present embodiment is identical with the first layer 50 according to the first embodiment except that it is a multilayer stack made of a plurality of layers. In other words, the material and the functions of the first layer 51 according to the present embodiment are the same as those of the first layer 50 according to the first embodiment. The first layer 51 is electrically conductive.

The first layer 51 according to the present embodiment has a structure obtained by stacking a plurality of first layers 51A to 51F in the thickness direction.

Specifically, the present embodiment includes, between the second layer 52 and the supporting member 24, a fourth layer 54A, a fourth layer 54B, a fourth layer 54C, a fourth layer 54D, a fourth layer 54E, and a fourth layer 54F stacked in this order from the second layer 52 to the supporting member 24.

The fourth layers 54 (fourth layers 54A to 54F) include areas made of the same material as the material of the first layer 50 according to the first embodiment (that is, areas that satisfy the same functions and requirements as those of the first layer 50). These areas correspond to the first layers 51A to 51F.

In the example illustrated in FIG. 14, a part of the fourth layer 54A corresponds to the first layers 51A and 51B. A part of the fourth layer 54B corresponds to the first layer 51C. A part of the fourth layer 54C corresponds to the first layer 51D. A part of the fourth layer 54D corresponds to the first layer 51E. A part of the fourth layer 54E corresponds to the first layer 51F. The fourth layer 54F includes no first layer 51.

The areas other than the first layers 51A to 51F in the fourth layers 54 (fourth layers 54A to 54F) simply need to be made of an insulating material having a smaller average atomic weight than that of the first layer 51, for example.

Similarly to the first layer 50 according to the first embodiment, the first layer 51 is preferably arranged such that a first projection area obtained by projecting the first layer 51 onto the light detecting unit 34 covers at least the light detecting unit 34.

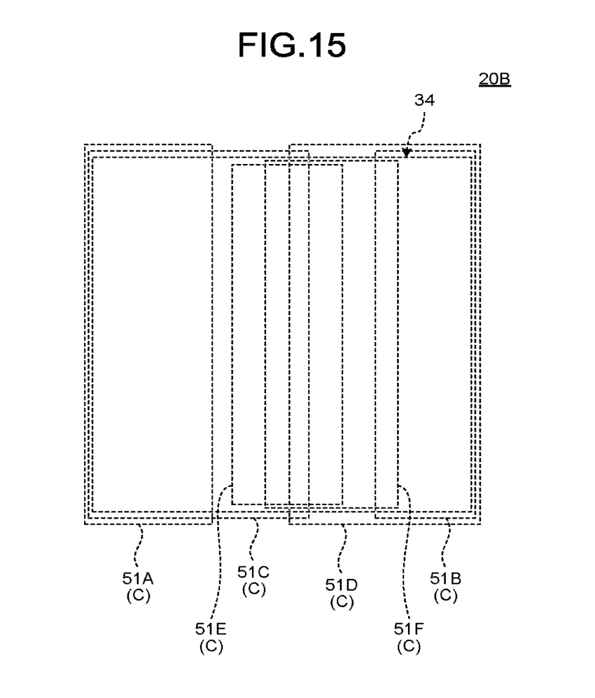

FIG. 15 is a plan view schematically illustrating an example of the photodetector 20B viewed from the light detecting unit 34. As illustrated in FIG. 15, a first projection area C obtained by projecting the first layer 51 (first layers 51A to 51F) onto the light detecting unit 34 preferably covers at least the light detecting unit 34. The first layers 51A to 51F constituting the first layer 51 preferably have such sizes in the plane direction and are arranged at such positions that the first projection area C of the first layer 51 covers the light detecting unit 34.

Referring back to FIG. 14, the first layer 51 (first layers 51A to 51F) according to the present embodiment is electrically conductive. Specifically, in the example illustrated in FIG. 14, the first layer 51A is electrically connected to the light detecting unit 34 via through electrodes 49. The first layer 51A is also electrically connected to the signal lines 23 via the through electrodes 49, the first layer 51C, and the first layer 51E. The first layer 51B is electrically connected to the signal lines 23 via the through electrodes 49, the first layer 51D, and the first layer 51F.

The sums of the thicknesses of the first layer 51 at respective positions along the plane direction are preferably equal at any position of the first layer 51 along the plane direction. In other words, as illustrated in FIG. 14, the sums of the thicknesses of the first layers 51A to 51F at respective positions in a direction (plane direction) orthogonal to the thickness direction of the photodetector 20B are preferably equal to one another.

The thicknesses of the first layers 51A to 51F may be equal to or different from one another. The positions and the ranges of the first layers 51A to 51F are not limited to those illustrated in FIG. 14.

As described above, the first layer 51 of the photodetector 20B according to the present embodiment is a multilayer stack made of a plurality of lavers (first layers 51A to 51F).

Also in this case, the photodetector 20B can provide the same advantageous effects as those of the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photodetector comprising:
light converting unit that converts radiation into light;
a first layer that absorbs the radiation;
a light detecting unit that is provided between the light converting unit and the first layer and detects light; and
a second layer that is provided between the first layer and the light detecting unit, has a smaller average atomic weight than an average atomic weight of the first layer, and absorbs radiation scattered in the first layer and a fluorescent X-ray generated in the first layer.

2. The photodetector according to claim 1, wherein the second layer includes an element having a smaller atomic number than an atomic number of an element of the first layer.

3. The photodetector according to claim 1, wherein the first layer includes at least one kind of element selected from Ag, Cu, Fe, and Mo.

4. The photodetector according to claim 1, wherein the second layer includes at least one kind of element selected from Si, Al, and Mg.

5. The photodetector according to claim 1, wherein the second layer has a thickness of equal to or larger than 0.5 mm.

6. The photodetector according to claim 1, wherein the first layer is a multilayer stack made of a plurality of layers.

7. The photodetector according to claim 1, wherein the first layer is arranged such that a first projection area obtained by projecting the first layer onto the light detecting unit covers the light detecting unit.

8. The photodetector according to claim 1, wherein the second layer is arranged such that a second projection area obtained by projecting the second layer onto the light detecting unit covers the light detecting unit.

9. The photodetector according to claim 1, wherein the first layer is electrically conductive.

10. The photodetector according to claim 9, further comprising:
a ground layer that is not electrically connected to the light detecting unit and is electrically connected to the first layer; and
a wiring layer that is provided between the ground layer and the first layer and is electrically connected to the light detecting unit.

11. A detecting apparatus comprising the photodetector according to claim 1.

12. A detecting system comprising:
a light source that emits radiation;
a light converting unit that converts the radiation into light;
a first layer that absorbs the radiation;
a light detecting unit that is provided between the light converting unit and the first layer and detects light; and
a second layer that is provided between the first layer and the light detecting unit, has a smaller average atomic weight than an average atomic weight of the first layer, and absorbs radiation scattered in the first layer and a fluorescent X-ray generated in the first layer.
